(19) United States
(12) Patent Application Publication
(10) Pub. No.: US 2016/0037924 A1
(43) Pub. Date: Feb. 11, 2016

(54) Movement Assembly and Method for Movement of a Display Device

(71) Applicant: Paul Bromley, Holmfirth (GB)

(72) Inventor: Paul Bromley, Holmfirth (GB)

(21) Appl. No.: 14/783,040

(22) PCT Filed: Apr. 7, 2014
(86) PCT No.: PCT/GB2014/051081

§ 371 Date: Oct. 7, 2015

(30) Foreign Application Priority Data
Apr. 8, 2013 (GB) 1306337.5

(51) Int. Cl. A47B 97/00; H05K 5/00; A47B 81/06

(52) U.S. Cl. CPC A47B 97/001; A47B 81/062; A47B 81/064; A47B 81/065; H05K 5/0017

(57) ABSTRACT

The invention relates to a movement assembly (2) particularly, although not necessarily exclusively, for use in the movement of an item in the form of a display screen (20) between a number of possible positions within a predefined environment and/or the possibility of altering the height and/or angle of the display screen at the particular location. The display screen is mounted on a bracket (14) which is moveable and which, in turn, is mounted on a movement assembly including a vehicle (12) for movement along guide means and drive means are provided to allow the movement assembly to be moved in response to remote control signals and/or in a predesignated manner to the required position and provide the display panel at the required orientation.

The invention to which this application relates is a movement assembly and particularly, although not necessary exclusively, a movement assembly which allows the movement of an item in the form of at least one display screen between a number of possible locations for viewing. The movement assembly can also allow the particular orientation of the display screen at a particular location to be selected and controlled and furthermore, allow power and/or video data and/or audio data to be provided to the display screen so that the same is operational at any selected location.

The provision of display screens with or without audio speakers, is well known. Most typically, the display screen is mounted on a stand at a fixed location, or on a support surface, such as a wall, at a fixed location thereon. It is also known to allow the tilt angle of the display screen to be adjusted to suit user's requirements in certain types of mount. It is also known to provide mounting systems which allow the mechanical movement of audio visual units to particular locations along guides which are located on for example, a ceiling or support frame. However, in practice, it is found that these known systems, while allowing the mechanical movement, are typically moved manually be the person wishing to view the screen at a convenient position. Thus, if powered movement is required, separate means are required to be provided in order to allow power and/or data to be provided to allow the operation of the display screen. This is typically provided via one or more cables, which are required to be of a length so as to allow the furthest possible location of the display screen from a base to be connected to be provided with the data and power services but this, in turn, means that when the display screen is provided at a closer location to the source of the power and data cables, then the excess length of the power and data cables need to be accommodated which can be unsightly and/or can cause the cabling to become snagged.

Thus, at present, the conventional movement systems are problematic and, as a result, their use is very limited.

A first aim of the present invention is therefore to provide a movement assembly which allows for the accurate, controlled, movement of an item, such as a display screen, to a desired location on guide means and a further aim is to allow the continued operation of the display screen during movement and when stationary at a particular location. A yet further aim is to allow the movement of the movement assembly to be powered and controllable without direct user contact being required with the display screen.

In a first aspect of the invention, there is provided a movement assembly, said movement assembly comprising a bracket to which an item to be moved by the movement assembly can be attached, said bracket connected to a vehicle which is located for movement along guide means along at least a first axis of movement and wherein said guide means include data and/or power connections along at least a portion thereof for connection with at least one connector provided on said vehicle as the same is moved along and/or located at a position on said portion of the guide means so as to allow the provision of digital data and/or a power supply for the operation of the said item and/or movement assembly.

In one embodiment, the item is a display screen and video and/or audio data is supplied to the said display screen to allow the generation of video and/or audio therefrom and a power supply is provided to said display screen to allow the operation of the same.

Typically, a first connector is provided on the vehicle for connection with the power supply and at least a second connector is provided for connection with the data supply.

In one embodiment, the data is provided in the form of HDMI data and is carried along a power line carrier (PLC) system. The PLC system can also be used to provide an Ethernet data service throughout the system and which is available to be used by the display screen mounted in connection therewith. In an alternative embodiment the data is provided to a receiver provided with the item by a wireless communication system and the power is carried by the connections on the guide means.

Typically the connectors are biased towards the power and/or data connections such that when the vehicle is located to move along the guide means portion, the connectors are biased to make a connection and retain the connection during movement of the vehicle along the guide means. Preferably, the video and/or audio generated by the display screen, is substantially continuously generated during the location of the display screen at a fixed location and, in one embodiment, also during movement of the vehicle.

Typically, said portion of the guide means along which the power and data supplies are provided, extend along substantially all of the guide means of the movement assembly.

In one embodiment, the guide means are provided along a single axis. In another embodiment the guide means are provided to allow movement of the vehicle along at least first and second axes which, most typically, are perpendicular. In another embodiment, a portion of the guide means may be curved and/or may be provided on a horizontal, and/or sloped and/or vertical support surface.

In one embodiment the guide means are provided such that the external face thereof and the face from which the vehicle depends is substantially flush with the adjacent support surface for the guide means.

Typically the construction of the guide means is achieved and the particular configuration of the same is selected by the user as the guide means can be constructed by selecting and joining together selected guide means units. In one embodiment the units can include different lengths, T sections, cross sections and/or curved sections.

Typically, the movement of the vehicle with respect to the guide means is powered, with the power being provided by the power supply connection running along the guide means.

In one embodiment, the apparatus includes a turntable arrangement which allows the orientation of the vehicle and/or bracket with respect to the guide means to be changed so as to allow the vehicle to travel along a different part of the guide means. In one embodiment the turntable includes docking means to ensure that the vehicle is in the correct position on the turntable prior to allowing powered movement of the turntable with the vehicle located thereon.

In one embodiment, the bracket includes a member which depends from mounting means to the vehicle. In one embodiment the said member is telescopic to thereby allow user adjustment of the distance of the display screen from the guide means. In one embodiment the bracket is connected to the vehicle via a rotation assembly in order to allow the location of the display screen to be rotated to any location throughout 360 degrees to suit particular user requirements at any location on the guide means track. In one embodiment this is achieved using a motor with a drive wheel and slip ring connector located between the bracket and the vehicle.

In one embodiment, the bracket includes angular adjustment means so as to allow the tilt angle of the display screen to be adjusted to suit user requirements.

Typically the display screen also includes speakers.

In one embodiment, each of the movement components in the form of the adjustment of the tilt angle of the display screen, the rotational position of the display screen with respect to the vehicle, the movement of the vehicle along the guide means track and/or the movement of the turntable is powered and is controlled by the user via a remote control device, or a communication device using a suitable application which interacts with receiver located at or in connection with the vehicle and/or guide means of the movement assembly. Preferably the remote control device can be programmed to have one or memory selection means which can result in the display screen being moved to a predetermined location and/or orientation.

In one embodiment, the remote control receiver may be common to the interface which is used to control the operation of the display screen.

In one embodiment the remote control device can be any, or any combination, of an Infrared (IR), Radio Frequency (RF) device and/or a smart phone, tablet device or any other device capable of emitting control signals therefrom.

Typically the control of the operation of the system is achieved via IP or RS232 control systems.

In one embodiment, the guide means are provided to receive and allow movement therealong of a plurality of vehicles, the location of which can be controlled, in combination, or independently. Typically each of the vehicles will be connected to a bracket on which a display screen can be mounted.

Typically sensing means are provided on the guide means to prevent vehicles from coming into contact with each other when moving along the guide means and/or to maintain the vehicles at a set distance apart.

In one embodiment the bracket with the rotational movement assembly is provided as a first assembly option, the bracket with the rotational movement assembly and a linear guide means track is provided as a second assembly option and the bracket with the rotational movement assembly, linear guide means and one or more turntables is provided as a third assembly option.

In a further aspect of the invention there is provided a movement assembly, said movement assembly including a bracket to which an item to be moved by the movement assembly can be attached, said bracket including a column located to depend downwardly from a support surface and movement means including one or more powered motors to allow one, or any combination, of a tilting movement of the item with respect to the column, telescopic movement of the column and/or rotational movement of the column and item thereon with respect to the support surface.

In a yet further aspect of the invention there is provided a movement assembly, said movement assembly including a bracket to which an item to be moved by the movement assembly can be attached, said bracket attached to a vehicle which is provided to be movable along a guide means, said vehicle and/or guide means including at least one motor to allow powered movement of the vehicle and hence bracket and item along said guide means, with the electrical power connection means for the at least one motor provided integrally with and along the guide means.

In one embodiment the movement assembly guide means include at least one turntable assembly which allow the vehicle, when located therewith, to be rotated and then moved along guide means along one of a plurality of axes.

In a further aspect of the invention, there is provided a method for movement of a display screen, said method comprising providing guide means to define a path or paths along which the display screen can be moved and located, providing at least one vehicle for movement along said guide means, providing on said vehicle a bracket, mounting said display screen on said bracket, providing control means to allow control signals to be generated by a user to determine the movement and/or location of the vehicle with respect to the guide means, and/or the position of the display screen with respect to the vehicle and wherein the movement of the vehicle with respect to the guide means is powered by contact made between a connector provided on the vehicle and a power supply connection running along at least a portion of the guide means and data is provided for the operation of the display screen.

In one embodiment the data is provided by a connector on the vehicle and a data supply connection running along at least a portion of said guide means. Alternatively the data is provided to the display screen via a wireless communication system.

In one embodiment, means are provided to determine the location of the vehicle with respect to the guide means and/or the premises in which the same is provided.

In one embodiment, the detected location of the vehicle is used to determine the particular operation of the display screen and/or the position of the display screen and/or movement of the display screen at the determined location. Thus, for example, if a detected location, matches that at which a particular product display is located in a shop, the operation of the display screen can be controlled to show video which is linked to the products at that location and/or the display screen may be moved to a particular orientation or height at said detected location. In one embodiment the movement of one or multiple vehicles on the guide means can be controlled to allow the movement of the same automatically to predetermined locations and/or cause media messaging, digital signage, advertising and/or TV programs with respect to the predetermined location.

In one embodiment, a plurality of vehicles are mounted for movement along the guide means at any given time and can be controlled in combination or independently.

In one embodiment the vehicles can be selectively introduced onto the guide means and removed therefrom by removing a portion of the guide means. Typically the portion which is removed is an end cap at one end of the guide means.

Specific embodiments of the invention are now described with reference to the accompanying drawing wherein;

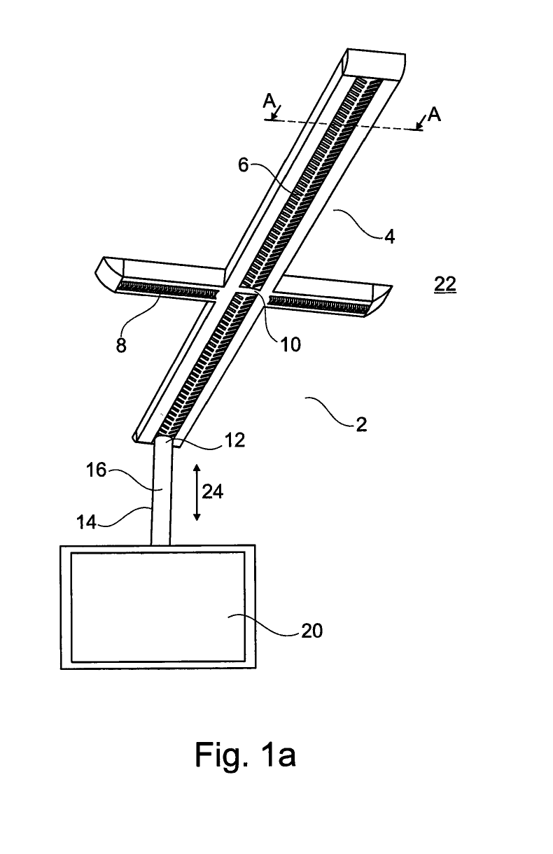

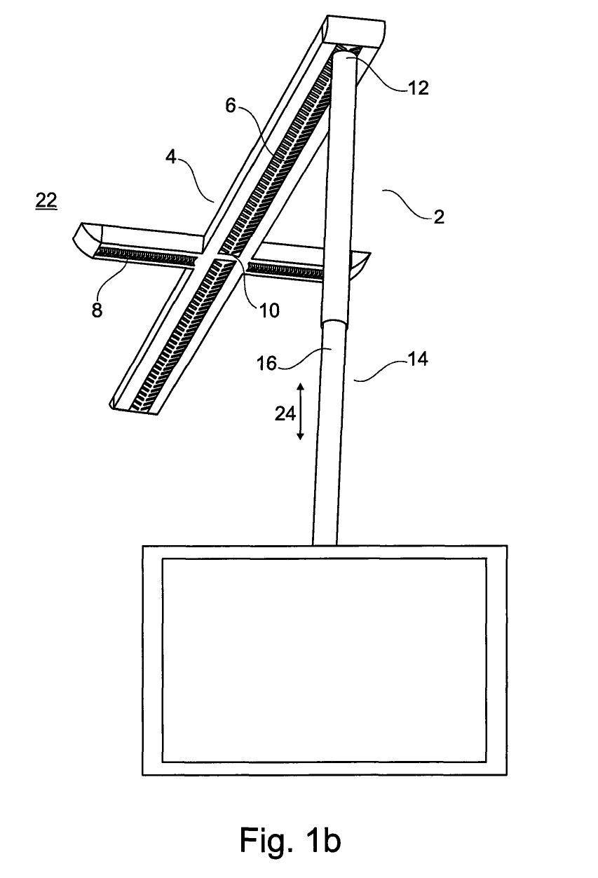

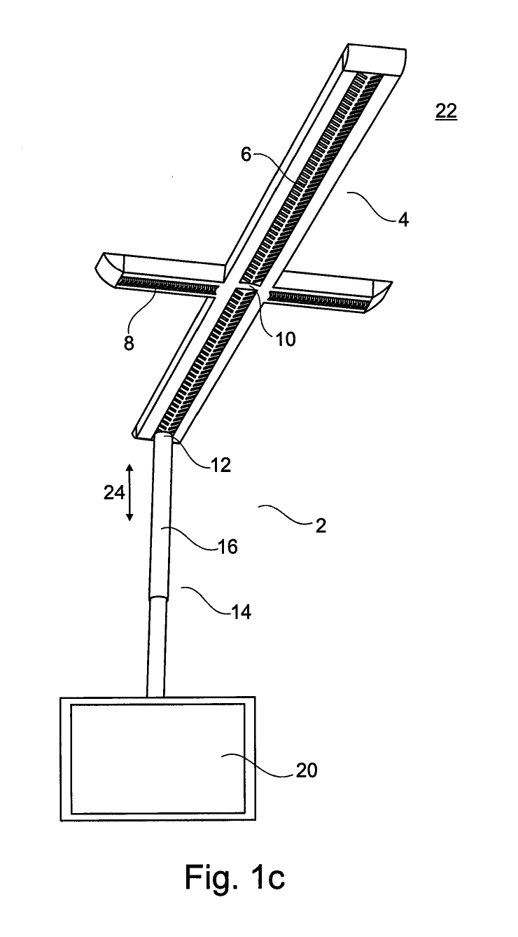

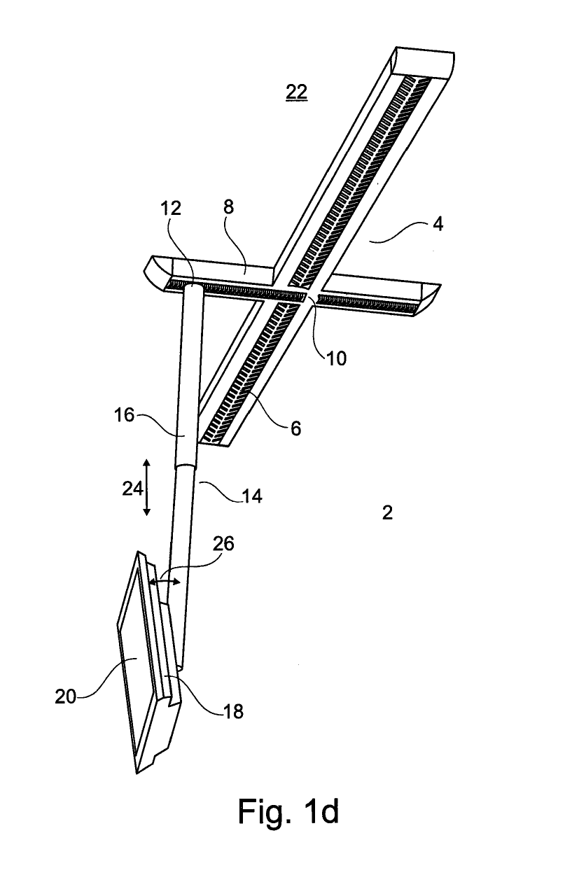

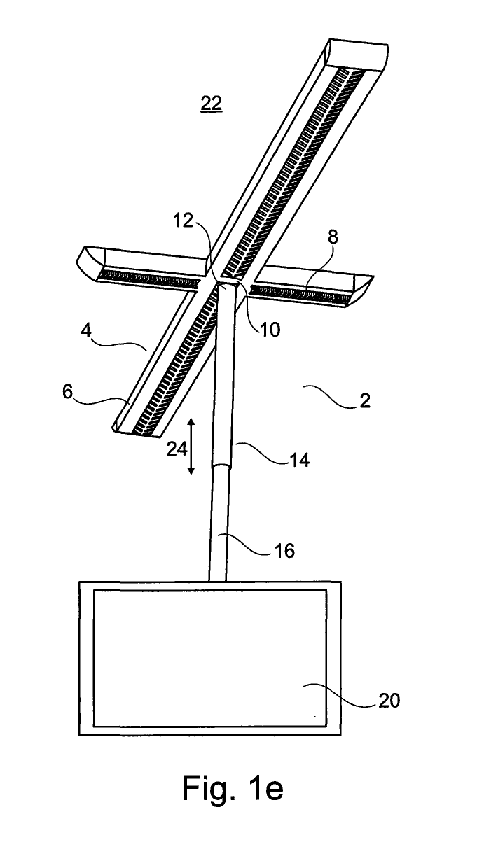

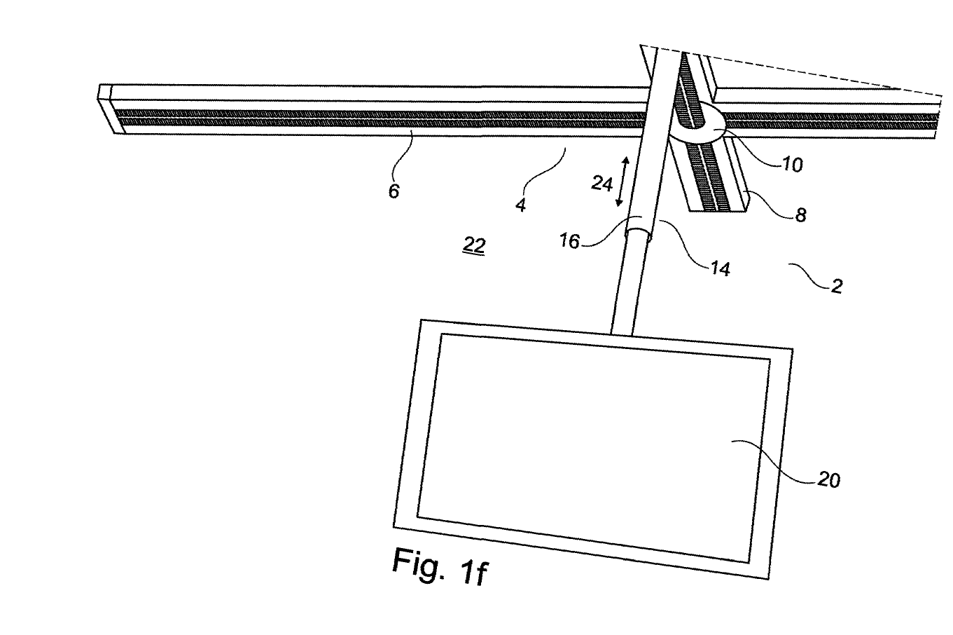

FIG. 1a-f illustrate a first embodiment of a movement assembly according to the invention;

FIGS. 1g-h illustrate a further embodiment for the mounting of the guide means;

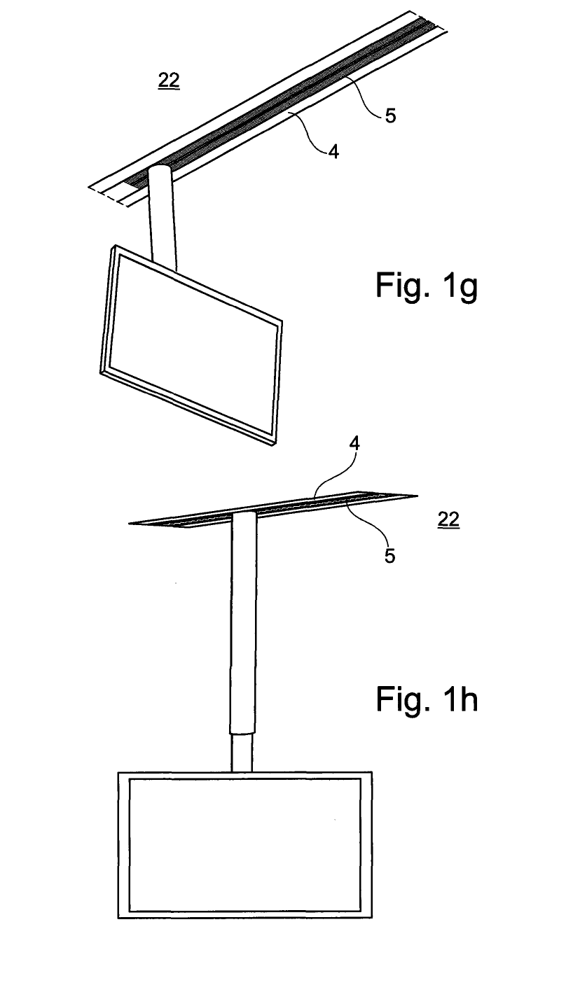

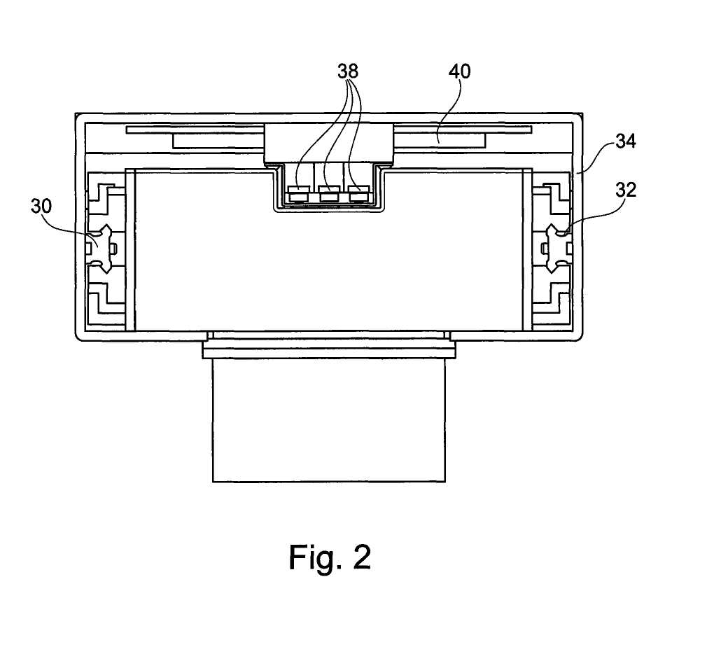

FIG. 2 illustrates a cross-sectional view of the guide means in accordance with a first embodiment of the invention;

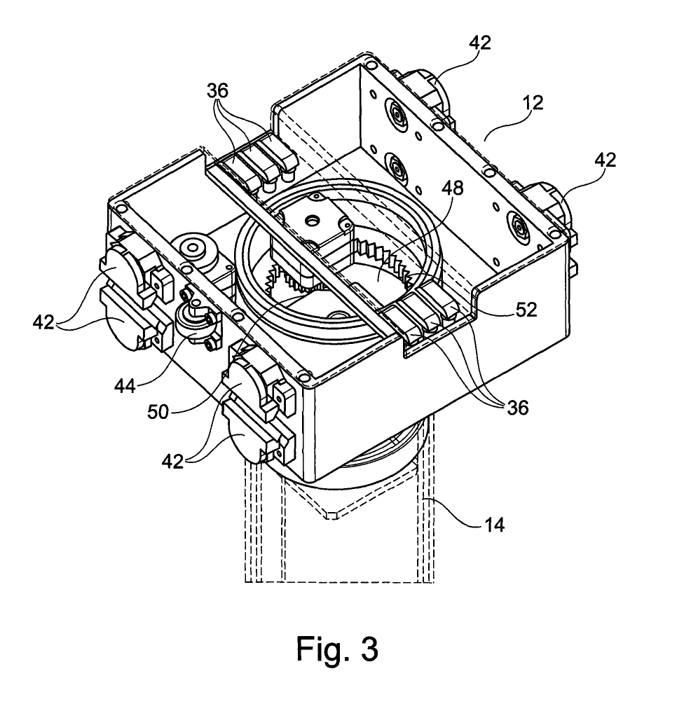

FIG. 3 illustrates a view of a vehicle in accordance with a first embodiment of the invention;

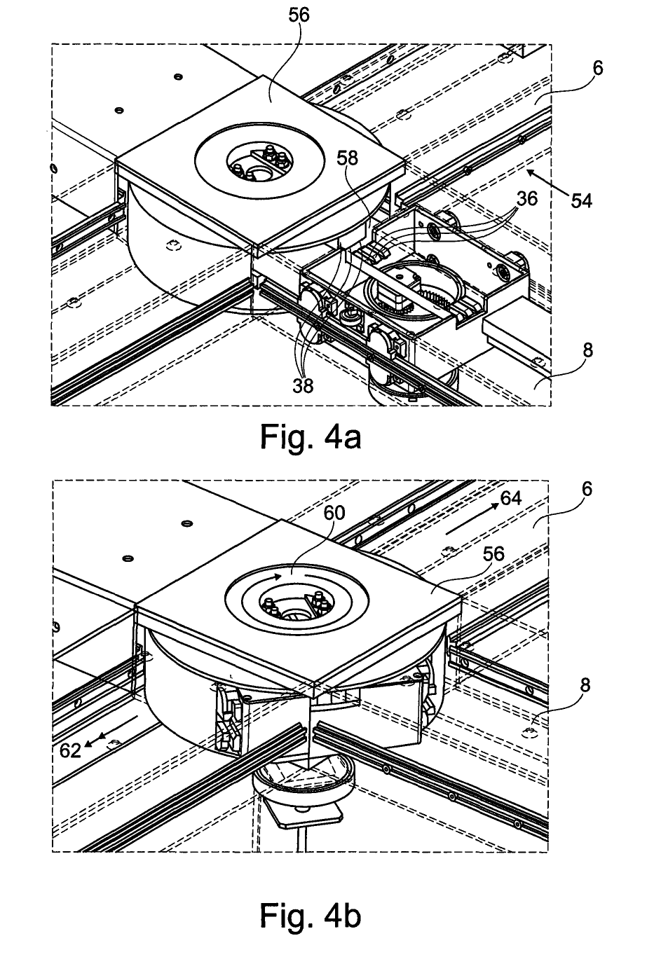

FIGS. 4a and b illustrate the vehicle and turntable arrangement in accordance with the first embodiment of the invention;

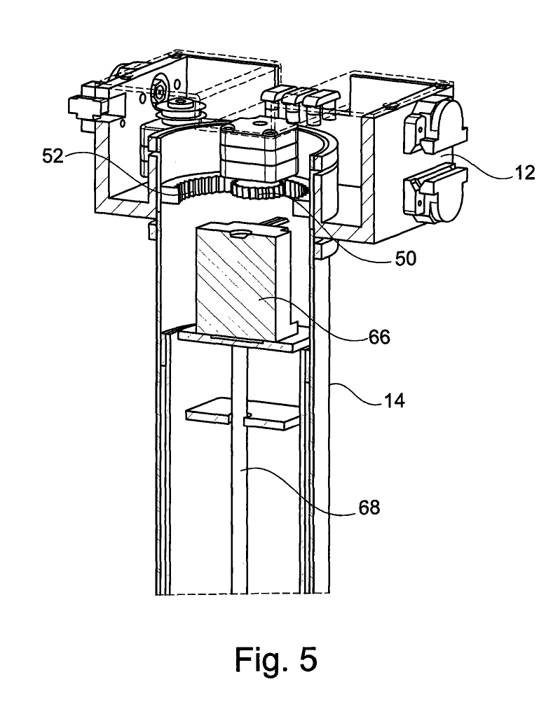

FIG. 5 illustrates the arrangement for adjustment of the height of the display screen in accordance with the first embodiment of the invention;

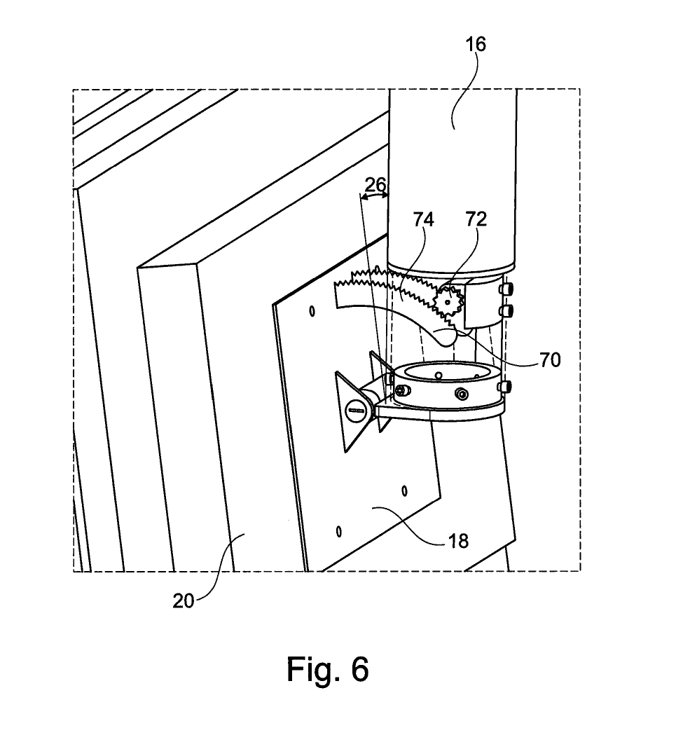

FIG. 6 illustrates one embodiment of an assembly to allow the tilt angle of the display screen to be adjusted;

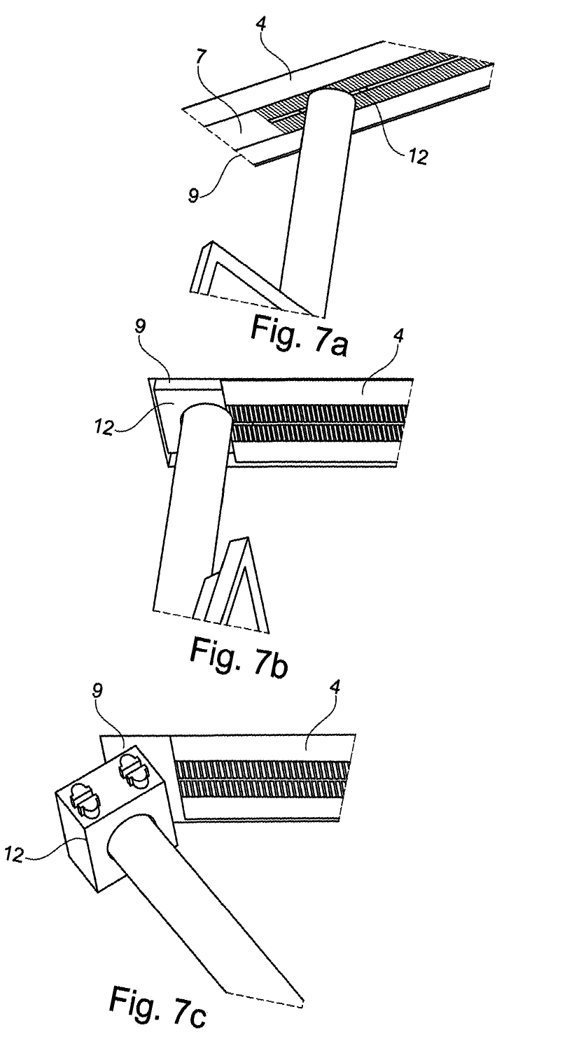

FIGS. 7a-c illustrate the manner in which the vehicle may be introduced and removed from the guide means;

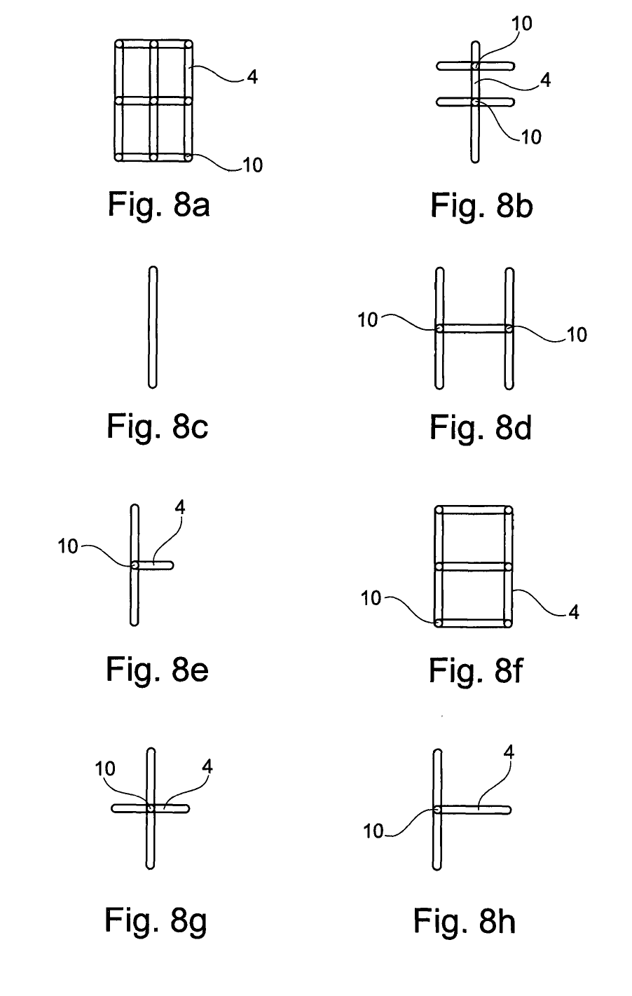

FIGS. 8a-g illustrate further possible embodiments of configurations of the guide means tracks;

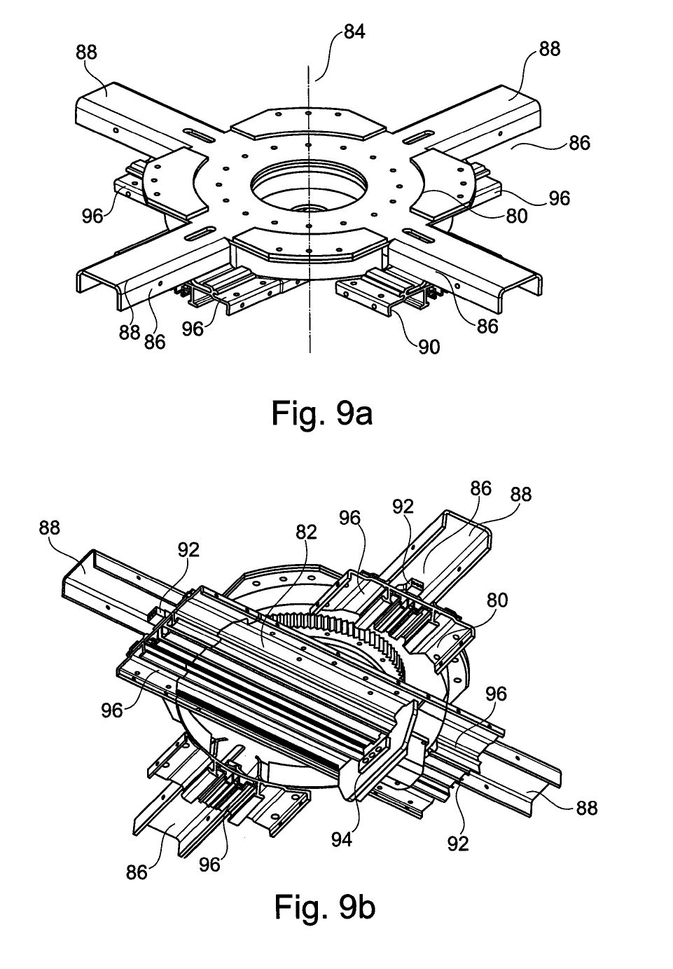

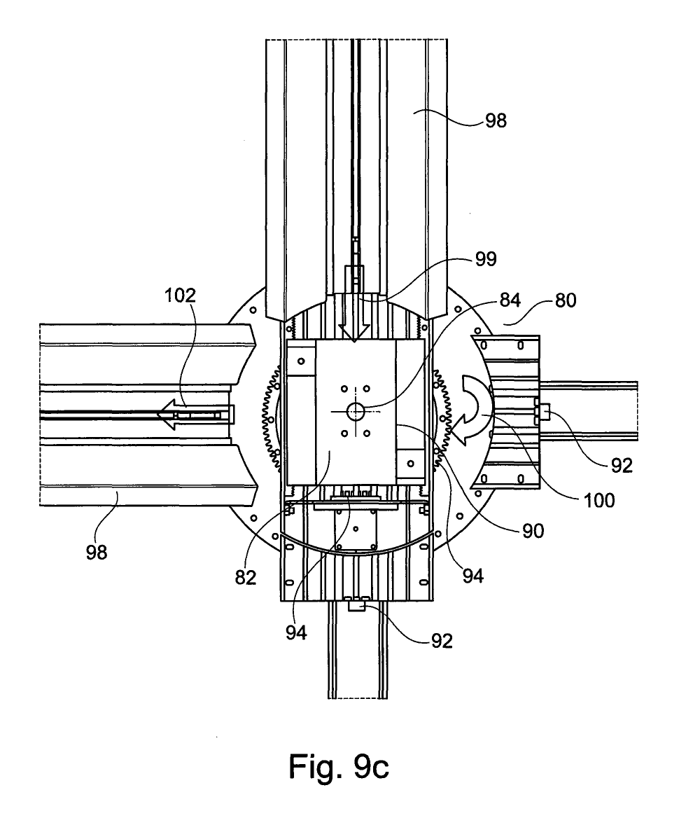

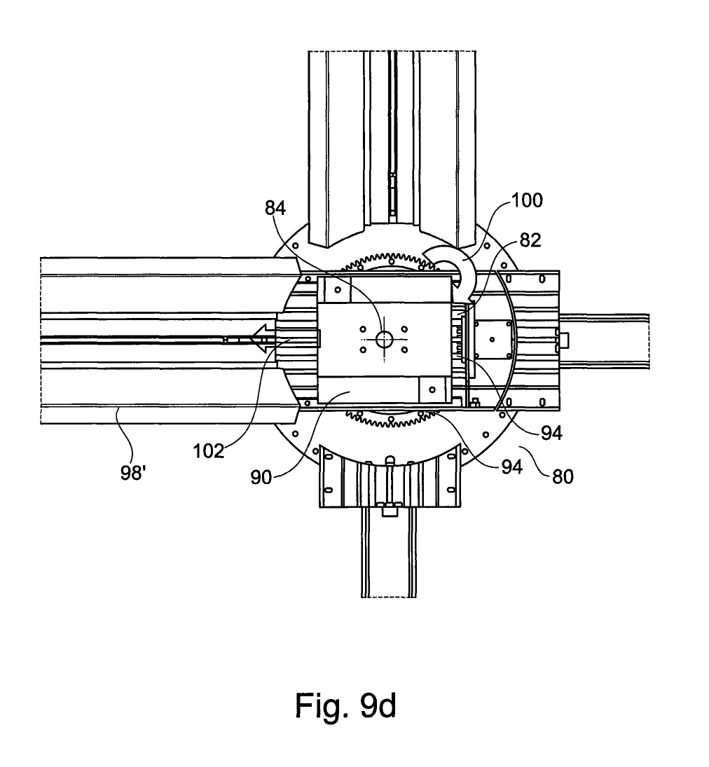

FIGS. 9a-d illustrate a second embodiment of a turntable arrangement in accordance with the invention;

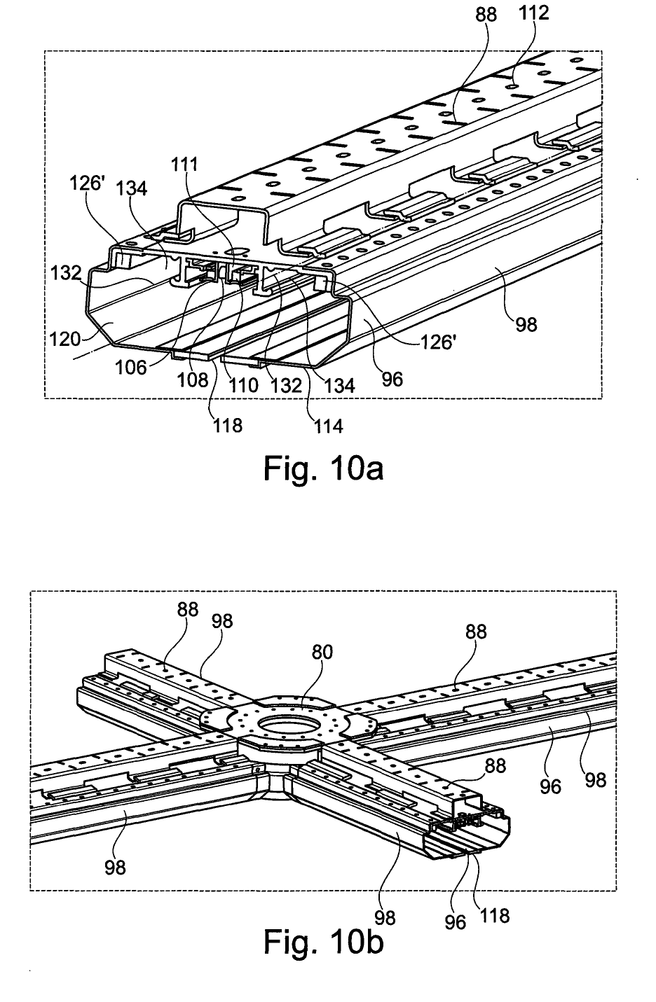

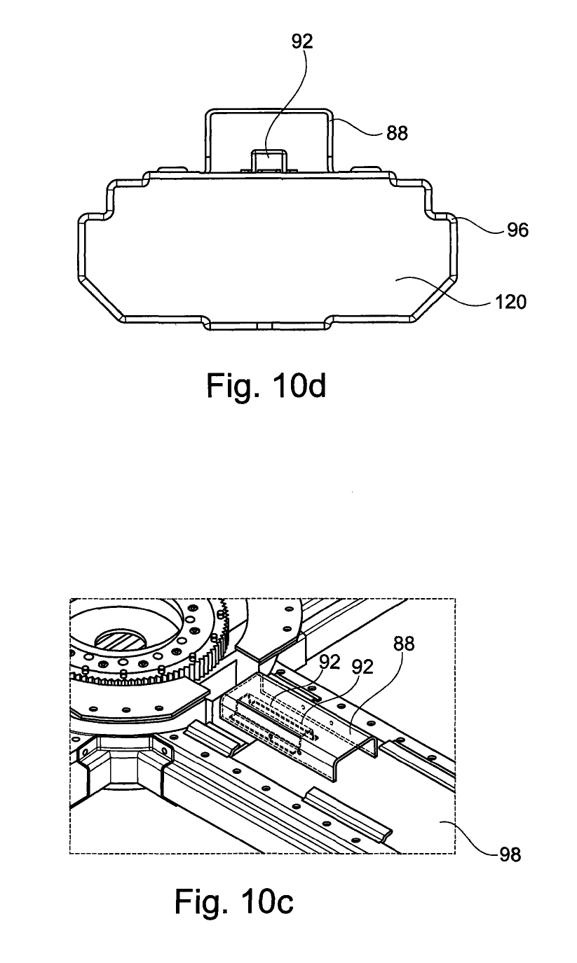

FIGS. 10a-d illustrate perspective views of part of a guide means track in accordance with a second embodiment of the invention;

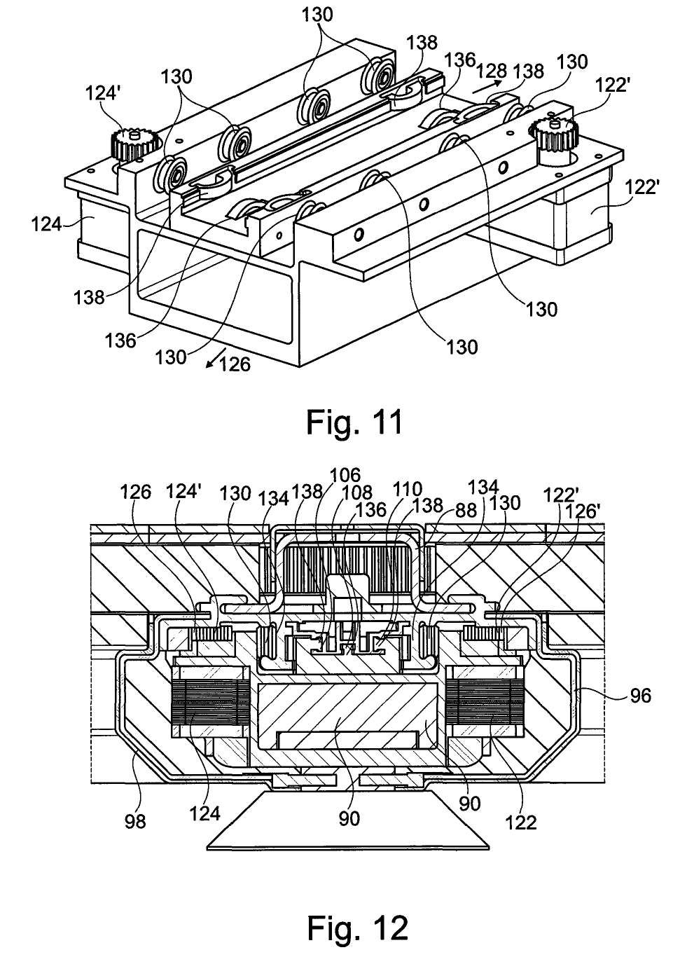

FIG. 11 illustrates a second embodiment of a vehicle in accordance with the invention;

FIG. 12 illustrates a cross sectional elevation of the guide means track and vehicle in engagement in accordance with the second embodiment of the invention;

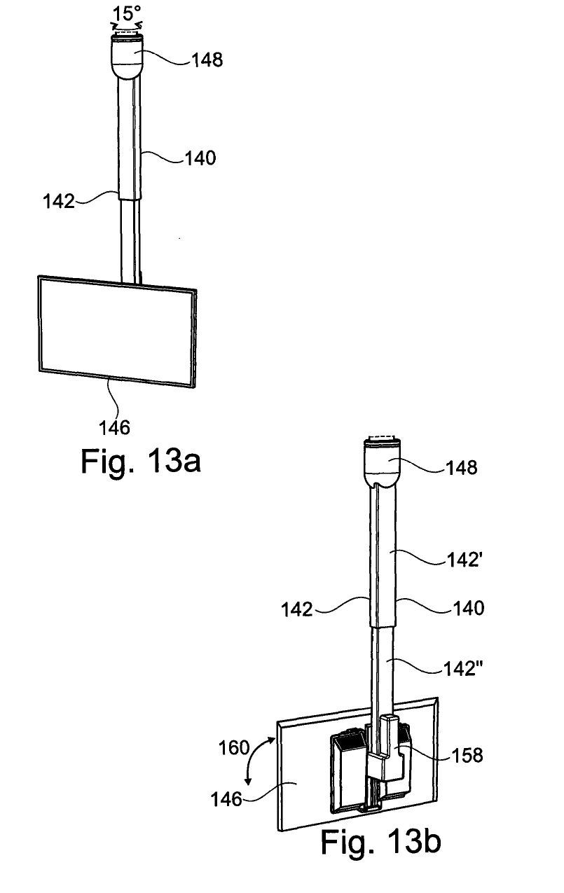

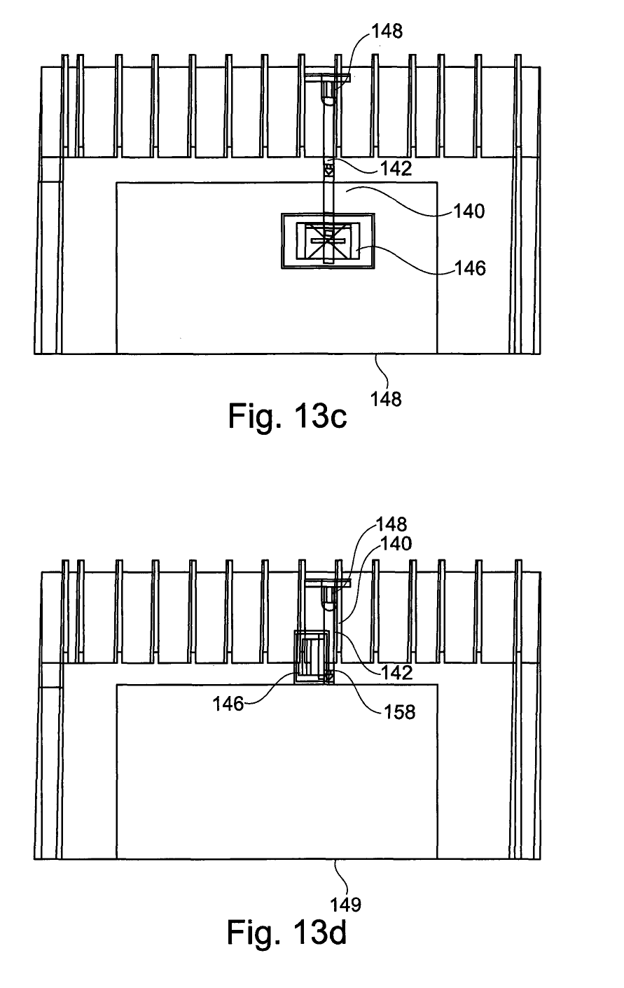

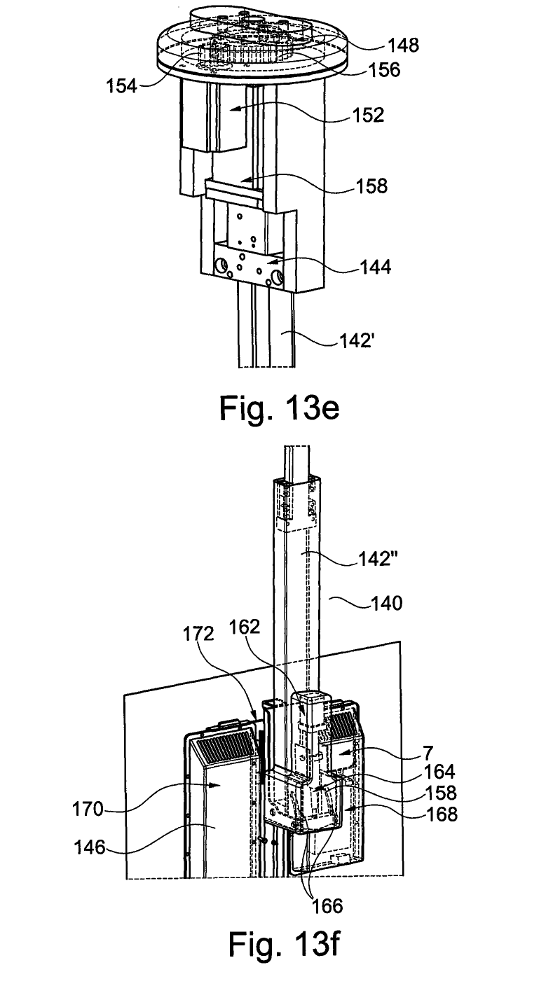

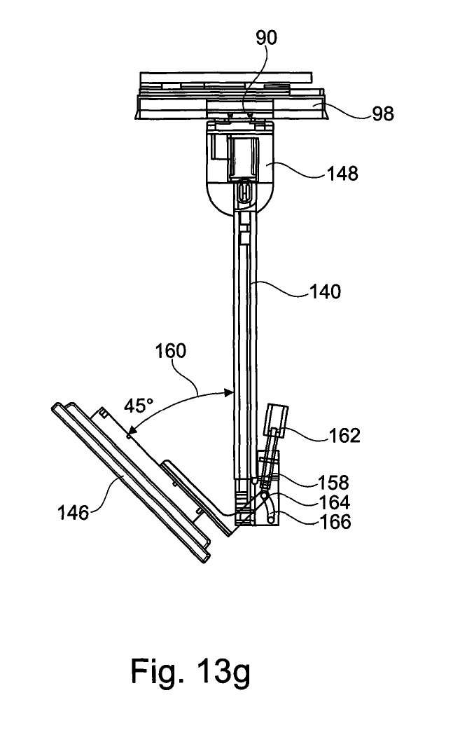

FIGS. 13a-d illustrate the arrangement of the bracket and the movement of the same in accordance with a second embodiment of the invention;

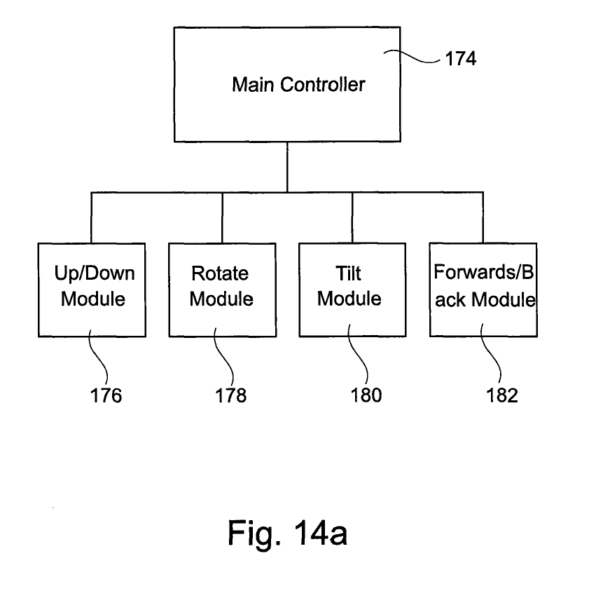

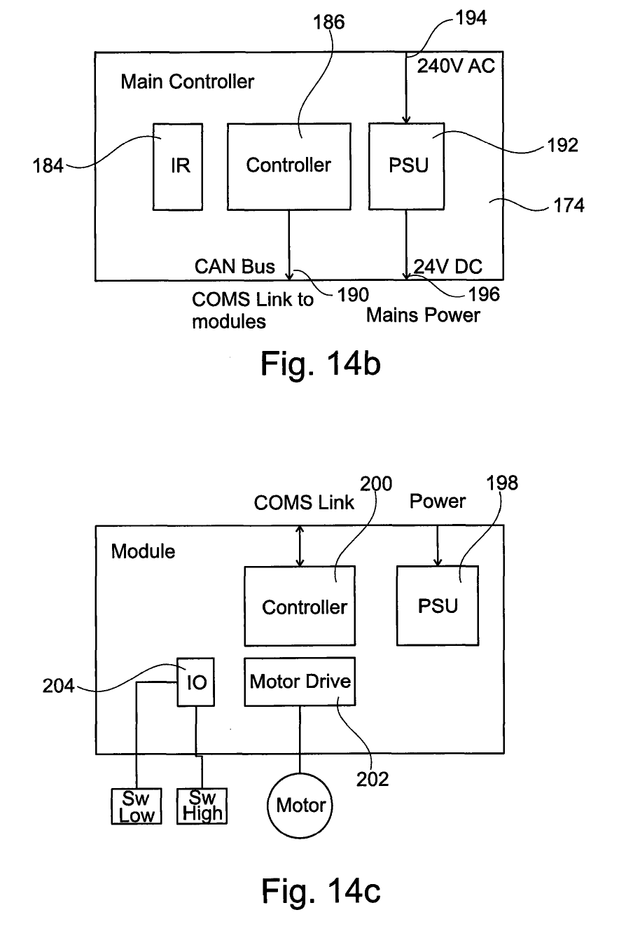

FIGS. 14a-c illustrate an example of control system for the apparatus of the invention; and

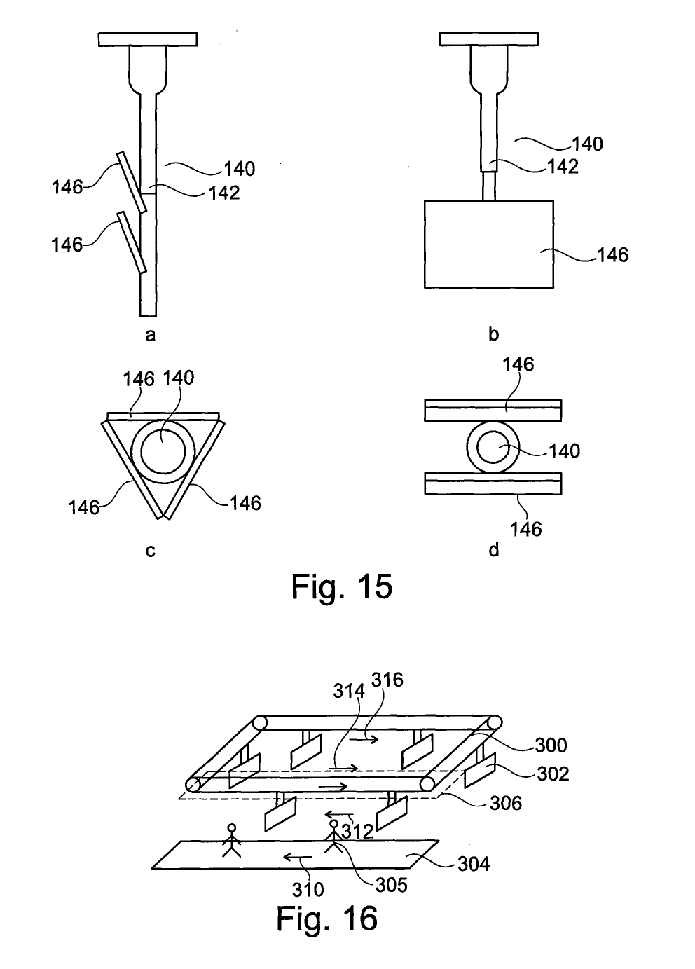

FIG. 15 illustrates possible arrangements of multiple screens for use with further embodiments of the apparatus.

Referring firstly to FIG. 1a-f there is illustrated a movement assembly 2 in accordance with one embodiment of the invention. The assembly comprises guide means 4 which in this embodiment are provided in the form of a cross to allow movement along axes 6,8 and at the location of intersection there is provided a turntable arrangement 10 which will be described in greater detail subsequently. Mounted on the guide means is a vehicle 12 and, to the vehicle 12 there is mounted a bracket 14 which includes an elongate member 16 and a mounting plate 18. A display screen 20 is mounted on the mounting bracket.

The guide means are mounted in this case on a support surface in the form of ceiling 22 of a room such that the guide means are horizontal. However in other embodiments the guide means can be mounted on a support surface such as a wall so that the guide means are vertical or lie at an angle between horizontal and vertical and the principals of operation described herein apply equally to these other arrangements of the guide means.

Further embodiments of configurations of the guide means track are shown in FIGS. 8a-g. FIGS. 8a and f show configurations of a grid type of guide means track 4 in which a number of turntable arrangements 10 are provided at a number of locations in order to allow the transfer of the vehicle between different guide means tracks. FIGS. 8b-g and g-h illustrate yet further embodiments and it will be appreciated that as the guide means track can be formed from a number of track sections which are joined together end to end, so there are a large number of possible configurations which can be selected to suit particular requirements. In whichever embodiment it will typically be the case that there is a predetermined “home” position for the apparatus and to which the apparatus returns for storage purposes or alternatively as a default position at which the display screen is required to be positioned at the majority of the time. When the home position is for storage the apparatus may move to a position at which the same is least obtrusive, for example, with the column of the bracket retracting to its shortest length. When the home position is a default position then the apparatus can move to the required predetermined arrangement for viewing.

As shown in the FIGS. 1a-f the vehicle 12 can be moved along the guide means to provide the display screen at any desired location along the guide means and can the display screen can be operated to generate video and/or audio at said locations and typically during movement between the said locations. Referring to FIGS. 7a-c the vehicle 12 can be selectively introduced onto the guide means 4 and removed therefrom by first removing the end cap 7 provided at one end 9 of the guide means as shown in FIG. 7a and thereby allow access to the guide means and for the vehicle 12 to be located at the end 9 as shown in FIG. 7b and then moved to be introduced to, or removed from, the guide means as required as shown in FIG. 7c. This allows the vehicle to be removed for maintenance and/or repair as required and also allows further vehicles to be introduced onto the guide means if required.

In addition to the movement of the vehicle with respect to the guide means, the elongate member 16 can also be adjusted in length as is indicated by arrow 24 so as to allow the distance of the display screen from the guide means to be adjusted. Furthermore the tilt angle 26 of the display screen as shown in FIG. 1d can also be selectively adjusted.

FIGS. 1g-h illustrate the manner in which, if required, the guide means 4 are mounted such that the external face 5 of the same is substantially flush with the adjacent support surface 22.

Typically, in all cases, the control of the movement parameters is achieved by a user using a remote control, which allows interaction with a signal interface and control means which allow the required movement to occur.

FIGS. 2-6 illustrates a first embodiment of the invention. FIG. 2 illustrates a cross sectional view along AA of the guide means 4. The guide means include first and second tracks 30,32 mounted on a housing 34. The tracks 30,32 engage with sliders 42 so that the movement of the vehicle is in a controlled manner along the guide means. The movement is achieved via at least one drive wheel 44 which contacts with the guide means. important in order to ensure that connectors 36 provided on the vehicle 12 as shown in FIG. 3 contact with power and data connections 38 to provide a power supply and video and/or audio data, typically utilising a Power Line Carrier (PLC) data transfer system. The connections 38 face downwardly from the top 40 of the guide means and which connections 38 are provided along the length of the guide means so that contact between the connectors and connections can be achieved and maintained at any location therealong and hence ensure operation of the display screen as power and data can be provided to the same at all times, and power can be supplied at all times to the vehicle to allow the movement of the same.

The vehicle is provided in location with the mounting bracket 14 and includes, as shown in FIG. 3, a rotation assembly 48 which comprises a drive toothed wheel 50 which can be rotated and which meshes with teeth in a circular path 52 and which is connected to the mounting bracket 14 so as to allow rotation of the mounting bracket with respect to the vehicle.

Turning now to FIGS. 4a and b, then in FIG. 4a the vehicle 12 is shown on the guide means 4 and approaching, as indicated by arrow 54 the turntable assembly 10 provided at the intersection between axes 6,8 of the guide means. As shown in FIG. 4b, the vehicle 12 enters the turntable assembly housing 56 and is located on a rotating platform 58 in which connections 38 are provided so as to maintain power and data connection with the connectors 36 of the vehicle 12 during movement of the turntable. When the vehicle is in position the same contacts with detectors 59 and this indicates that the vehicle is in a secure and correct position on the turntable. This then allows the platform 58 to be rotated along with the vehicle and hence bracket, as indicated by arrow 60 to bring the vehicle into line with another of the movement axes, in this case axis 6. The vehicle 12 can then move along the guide means along axis 6 in either of the directions 62, 64 to move the same to the required location in response to user generated control signals.

FIG. 5 illustrates the mounting bracket 14 in cross section at it's location with the vehicle and also shows the provision of a drive screw motor 66 with a screw shaft 68 which, when operated, allows the length of the member 16 to be adjusted and hence the height of the display screen and mounting means therefore to be adjusted. FIG. 6 illustrates the free end of the member 16 and illustrates the mounting plate 18 at the rear of the display screen 20 and illustrates that the mounting plate 18 is connected to the member 16 via a pivot arrangement 70 which allows the tilt angle 26 to be adjustable. Again this movement can be powered by powering rotation of the toothed wheel 72 to move it along the toothed member 74 and hence adjust the angle. The mounting plate and hence the apparatus can be range taking in terms of the size of the particular display screen which is to be mounted on the same and can, if required be adapted to include a further mounting plate to allow display screens to be mounted side by side and/or back to back.

Referring now to FIGS. 9a-d there is illustrated a turntable arrangement 80 according to a further embodiment of the invention. As before, the arrangement comprises a rotatable portion 82 which is mounted to be rotatable about an axis 84. In this case four track guide means 86 are provided spaced apart by 90 degrees and each of these can be selected to receive the vehicle 90 therealong. Each of the guide means tracks 86 includes a securing portion 88 which allows the arrangement to be secured to the ceiling or other support means and a track portion 96. Also shown are the connection plugs or sockets 92 which allow the same to be connected to a matching plug or socket mounted on the guide means section to be located therewith and thereby maintain the provision of power and/or data to the display screen and movement means of the apparatus wherever the location of the vehicle on the guide means. The connections typically carry live neutral and earth supplies 106, 108,110.

As in the first embodiment the vehicle is moved into position on the rotatable portion 82 and the portion includes detectors 94 such as an interlock and with which the vehicle 90 is required to engage before the rotation of the rotatable portion can commence. FIGS. 9c and d show plan views of the underside of the rotatable arrangement 80. When the vehicle 90 is moved in the direction of arrow 99 as shown in FIG. 9c from the guide means track 98 into the required position on the rotatable arrangement as shown, rotation of the vehicle can commence via the movement of the rotatable portion 82 as indicated by arrow 100 and in a response to a user control command via the provision of power to a motor which engages with the cog wheel 94. The rotatable portion 82 and hence vehicle 90 continues until the same is in line with the required track along which the vehicle is then to move, in this case guide means track 98′. When it is detected that the rotatable portion is in line with the guide means track 98′ the vehicle can be powered to move along the track as indicated by arrow 102 and it will be appreciated that this can be repeated for any of the guide means tracks leading from the rotatable arrangement 80.

FIGS. 10a-d illustrate the guide means track 98 in greater detail. The guide means track includes the securing portion 88 and the track portion 96. The securing portion can be provided with formation 112 to aid in the fixing of the same in position to a support surface and is secured in position, in turn, with the track portion 96 which, in one embodiment is manufactured from extruded aluminium.

Also carried along the track portion 96 are the electrical and/or data connections 106,108, 110 and which are connected together at the ends 114 via the engagement of matching plugs and sockets 92 as shown in FIG. 10c. The plugs and sockets 92 and the housings 111 for the electrical connections are typically made of insulating material in order to minimise the opportunity from access and hence electrical shock. Mechanical engagement means can also be provided to allow the aligned mechanical engagement of the tracks together. At the underside 116 of the track portions there is provided an elongate slot 118 along which the connection with the bracket moves as the vehicle moves along the cavity 120 within the track means. Brushes or other masking means may be provided along the slot 118 to mask the view of the cavity 120.

FIG. 11 illustrates another embodiment of the vehicle 90 and shows that the same is provided with first and second, diagonally offset motors 122, 124. The diagonal offset is found to assist in the appropriate alignment of the vehicle with respect to the guide means track, and drive of the vehicle in the directions 126, 128 is achieved by rotation of the cog wheels 122′, 124′ of the respective motors 122, 124 which engage with teeth 126, 126′ provided in a fixed linear manner along the length and on each side of the guide means track so as to move the vehicle along the track. The movement along the track is guided by a series of wheels 130 on each side of the vehicle and arranged along linear axes which are parallel with the axes 132 of the elongate formations 134 of the track portion 96 with which the wheels 130 engage. Electrical and/or data connectors are also provided on the vehicle in the form of portions 136, 138, typically formed of copper and biased towards an engaging position with the connections 106, 108, 110 on the track.

FIG. 12 illustrates an end elevation of the guide means track 98 in engagement with the vehicle 90 and illustrates the mutual engagement of the electrical and/or data connections 106,108,110 with the connectors 136, 138 of the vehicle and the wheels 130 of the vehicle with the elongate formations 134 of the track 96. Also shown is the engagement of the cog wheels 122′ 124′ with the elongate teeth racks 126, 126′ of the guide means track.

FIGS. 13a-g illustrate the bracket 140 in accordance with one embodiment of the invention. The brackets includes a telescopic column 142 which, in this case is formed of two parts 142′, 142″ which are telescopically movable under the influence of a linear actuator 144 powered by motor 158. This allows a range of vertical movement so as to allow the position of the display screen 146 to be raised and lowered a distance from the floor 149 of the room in which the same is installed and within a range indicated in FIGS. 13c and d. It should however be appreciated that the range can be increased or decreased to suit specific purposes and room sizes. The actuator typically acts in conjunction with one or more sensors so as to determine when the maximum and minimum extension has been reached.

At the top of the column 142 there is provided a rotatable assembly 148 and which is located at the interface and join to the vehicle 90 from which the same depends downwardly. The rotatable assembly allows rotation of the column and hence the display screen 146 through 360 degrees as illustrated by arrow 150. Typically the assembly includes a slip ring and cable management to ensure that there is no twisting or snagging of any cable connection which run from the vehicle 90 into the bracket in order to allow the power and/or data to be transferred to the bracket in order to operate the rotatable assembly 148, linear actuator 144 and the display screen. The rotatable assembly is powered by motor 152 which acts on cog wheel 154 which in turn engages with cog wheel 156 located n the column to rotate the same.

The bracket 140 further includes a mounting assembly 158 for the display screen 146. The mounting assembly engages with the rear of the display screen, typically using conventional display screen engagement locations. The assembly also allows for the powered tilting of the display screen as indicated with regard to arrow 160. This is typically achieved by means of use of a motor 162 which acts on a lever 164 to cause relative movement of the display screen to tilt the same about arcuate guides 166.

Typically, regardless of whether cable or wireless HDMI data is being transmitted to the display screen for video, audio and auxiliary services a receiver 168 is mounted at the rear of the display screen in order to receive the data to be used and send the same to the display screen control system. Also, the control system 170 for operation of the apparatus can be mounted at the rear of the display screen.

In one embodiment, if further linear movement of the display screen with respect to the bracket is required, a further linear slider 172 can be provided at the interface between the bracket and the display screen.

FIGS. 14a-c illustrate one embodiment of the components of a control system to allow operation of the apparatus. In one embodiment the movement of each of the modules, the turntable arrangement, the movement of the vehicle along the guide means and the movement of the bracket can be controlled separately and this is also of assistance if it is desired to supply only one or a combination of the possible modules. Thus there is provided a main controller 174 which is provided to allow control of separate movement control modules 176, which controls the linear movement of the column 142, module 178 which controls the rotation of the column 142, modules 180 which controls the tilting movement of the display screen 146, and module 182 which controls the movement of the vehicle along the guide means 98.

The main controller 174 is provided with a communication receiver 184 to receive control signals and which, in this case is an infra red signal receiver. A processor 186 is provided to receive the data from the receiver and generate the appropriate control signal to the apparatus to cause movement of the same via a communication link 190, typically via the electrical connections on the system. The Power Supply Unit (PSU) 192 is connected to a mains power supply 194 and then allows the conversion from 240V to 24 Volts and allows the converted power to be passed to the electrical connections of the system at output 196.

An embodiment of a module 176-182 is shown in FIG. 14c and the module is provided to receive power from the output 196 and the same is supplied to the PSU 198, a controller 200 is connected to the communications link 190 from the main controller and is connected to control the operation of the particular movement motor for the module via the motor drive control 202 along with Input and Output 204 to control the direction of movement of the motor.

It is envisaged that the apparatus of the invention can have several advantageous areas of use. One such area is with regard to use in a room of a domestic premises in which the apparatus will typically respond to user generated commands when, for example, the user may want to move to a different location to view the display screen and in which case the vehicle 90 is moved to the appropriate location on the guide means tracks and/or for example, when the user may want to use the screen for a different purpose or to view different video and/or audio and in which case the display screen may, for example, be tilted and/or lowered. In any event, in these circumstances, the movement which occurs will tend to be in response to a user actuated control signal and at other times the display screen and orientation of the same will be fixed.

In addition, or alternatively, the apparatus may be provided to move the display screen more frequently and/or continuously and it is envisaged that these uses will be more attractive to commercial opportunities such as, for example, retail premises, public spaces such as airports and the like where display screens are typically provided in a fixed location.

Thus in one embodiment of use and as mentioned already it is possible for a number of display screens to be mounted on the same bracket, possibly one above the other on the same column as shown in FIG. 15a and/or in respective angular orientations around the same column as shown in plan in FIG. 15b and/or in a back to back configuration as shown in plan in FIG. 15c and/or one display screen located on the column as shown in FIG. 15d. It is also possible that multiple vehicles are provided to be moveable along the guide means tracks at different spaced locations, and each of the vehicles having a bracket and at least one display screen depending downwardly therefrom.

In these embodiments it will typically be the case that the movement of the vehicle along the track is predetermined and therefore is not required to wait for specific control signals. For example, for the display of information relating to arrivals and departure the screens may be continuously rotates around the column 140 so as to ensure that the maximum number of customer can view the information on the display screens at regular intervals. Alternatively the screens may be controlled to rotate to a number of predetermined positions and then stop for a period of time to allow the information to be viewed and then move to the next position, then stop and so on in a step wise manner. In this arrangement it is possible that the apparatus will not include the guide means tracks so that the apparatus is not linearly movable with regard to a Y axis.

In addition or alternatively, when the guide means are provided the movement of the vehicle may be predetermined and the movement and location of the same may be linked between the video and/or audio which is to be shown on the display screen at a particular time so that if, for example, the apparatus is installed in a retail premises and the display screen is to show advertising material relating to specific products which are for sale, the display screen will be moved by the apparatus to a location adjacent the location in the retail premises at which those products are sold. Typically where multiple screens are provided to be movable along the same guide means each of the display screens can be independently controlled to display different video and/or audio and thereby allow the displays from the same to be tailored to match the particular location at which the display screen is at that time. The display screens can also be selectively controlled to provide information such as directions and emergency information as and when required.

Yet further, as illustrated in FIG. 16, the display screen or a number of spaced display screens 302 can be mounted and controlled to move in synchronisation with other movement means such as, for example, powered escalators or walkways 304, 306 such that the display screens effectively follow a person 308 as the person is being moved by the escalator or powered walkway. This therefore allows significantly greater exposure time to the information or advertising material being displayed on the display screen 302 than would be the case if the display screen was stationery and the person was moving past the same. Typically the track guide means 300 along which the display screen is moved in a controlled predetermined manner, matches the path of the escalator or walkway in a first direction 310 and the display screen can either return along the guide means track when it reaches the end of the track and then is moved again or alternatively if a second escalator or walkway 306 is provided as shown adjacent the first but moving in the opposite direction 314 then the guide means track 300 is provided as a loop and the display screens 302 then move along the second part 316 of the loop in spaced synchronisation with the second walkway 306, thereby allowing the display screen to be continually watched. In one embodiment the synchronised movement is at the same speed as the escalator or walkway or may be selected to be at a predetermined variation thereof.

1. A movement assembly, said movement assembly comprising a bracket to which an item to be moved by the movement assembly can be attached, said bracket connected to a vehicle which is located for movement along guide tracks along at least a first axis of movement and wherein said guide tracks include data and/or power connections along at least a portion thereof for connection with at least one connector provided on said vehicle as the same is moved along and/or located at a position on said portion of the guide tracks so as to allow the provision of digital data and/or a power supply for the operation of the said item and/or movement assembly.

2. A movement assembly according to claim 1 wherein the item is a display screen.

3. A movement assembly according to claim 1 wherein video and/or audio data is supplied via the guide tracks to the item to allow the generation of video and/or audio therefrom.

4. A movement assembly according to claim 1 wherein a power supply is provided via the guide tracks to the item to allow the operation of the same.

5. A movement assembly according to claim 4 wherein a first connector is provided on the vehicle for connection with the power supply and at least a second connector is provided for connection with the data supply.

6. A movement assembly according to claim 3 wherein the data is provided in the form of high definition multi-media interface and/or ethernet data and is carried along a power line carrier (PLC) system provided in the guide tracks.

7. A movement assembly according to claim 5 wherein the first and at least a second connectors are biased towards the power and/or data connections such that when the vehicle is located to move along the guide tracks, the first and at least a second connectors are biased to make a connection and retain the connection during movement of the vehicle along the guide tracks.

8. A movement assembly according to claim 3 wherein the video and/or audio generated by the display screen is substantially continuously generated during the location of the display screen at a fixed location and during movement of the vehicle.

9. A movement assembly according to claim 1 wherein the guide tracks are provided along a single axis.

10. A movement assembly according to claim 1 wherein the guide tracks are provided to allow movement of the vehicle along at least first and second axes.

11. A movement assembly according to claim 1 wherein the guide tracks are provided such that an external face thereof from which the vehicle depends is substantially flush with an adjacent support surface for the guide tracks.

12. A movement assembly according to claim 1 wherein the guide tracks are modular in construction.

13. A movement assembly according to claim 1 wherein the guide tracks include a turntable arrangement which allows orientation of the vehicle and/or bracket with respect to the guide tracks.

14. A movement assembly according to claim 1 further including a bracket with a member which is telescopic to thereby allow adjustment of the distance of the item from the guide tracks.

15. A movement assembly according to claim 14 wherein the bracket includes angular adjustment means so as to allow the tilt angle of the item mounting means with respect to the member to be adjusted to suit user requirements.

16. A movement assembly according to claim 1 wherein the guide tracks are provided to receive and allow movement therealong of a plurality of vehicles, location of which can be controlled, in combination, or independently.

17. A movement assembly according to claim 1 wherein movement of the movable parts is performed in response to a user generated command signal received by a receiver connected to the assembly.

18. A movement assembly according to claim 1 wherein movement of the movable parts is performed in a predetermined manner in response to control means which determine the location, type of movement and the frequency of movement which is to be performed.

19. A movement assembly according to claim 18 wherein the controlled movement is made with reference to the particular environment in which the assembly is located and/or the video to be generated by the display screen at a particular time.

20. A movement assembly, said movement assembly comprising:
a bracket to which an item to be moved by the movement assembly can be attached, said bracket including a column located to depend downwardly from a support surface; and
movement means including one or more powered motors to allow one, or any combination, of a tilting movement of the item with respect to the column, telescopic movement of the column and/or rotational movement of the column and item thereon with respect to the support surface.

21. A movement assembly, said movement assembly comprising:
a bracket to which an item to be moved by the movement assembly can be attached, said bracket attached to a vehicle which is movable along a guide track,
said vehicle and/or guide tracks including at least one motor to allow powered movement of the vehicle and hence bracket and item along said guide tracks, with an electrical power connection for the at least one motor provided integrally with and along the guide tracks.

22. A movement assembly according to claim 21 wherein the guide tracks include at least one turntable assembly which allow the vehicle, when located therewith, to be rotated and then moved along guide tracks along one of a plurality of axes.

23. A method for movement of a display screen, said method comprising the following steps of:
providing guide tracks to define a path or paths along which the display screen can be moved and located,
providing at least one vehicle for movement along said guide tracks,
providing on said vehicle a bracket,
mounting said display screen on said bracket,
providing control means to allow control signals to be generated by a user to determine the movement and/or location of the vehicle with respect to the guide tracks, and/or the position of the display screen with respect to the vehicle and
wherein movement of the vehicle with respect to the guide tracks is powered by contact made between a connector provided on the vehicle and a power supply connection running along at least a portion of the guide tracks and data is provided for the operation of the display screen.

24. A method according to claim 23 wherein the data is provided via a connector on the vehicle and a data supply connection running along at least a portion of said guide tracks.

25. A method according to claim 23 wherein the data is provided to the display screen via a wireless communication system.

26. A method according to claim 23 wherein means are provided to determine the location of the vehicle with respect to the guide tracks and/or the premises in which the same is provided.

27. A method according to claim 26 wherein the detected location of the vehicle is used to determine the particular operation of the display screen and/or the position of the display screen and/or movement of the display screen at the determined location.
